(19) United States
(12) Patent Application Publication
(10) Pub. No.: US 2012/0153285 A1
(43) Pub. Date: Jun. 21, 2012

(54) SOLUTION PROCESSABLE PASSIVATION LAYERS FOR ORGANIC ELECTRONIC DEVICES

(75) Inventors: Mark James, Romsey (GB); Nils Greinert, Stonehouse (DE); Miguel Carrasco-Orozco, Winchester (ES); Paul Craig Brookes, Southampton (GB); David Christoph Mueller, Frankfur am Main (DE); Philip Edward May, Sidcup (GB); Stephen Armstrong, Waverton (GB); Sivanand Pennadam, Broughton (GB)

(73) Assignee: MERCK PATENT GESELLSCHAFT MIT BESCHRANKTER HAFTUNG, Darmstadt (DE)

(21) Appl. No.: 13/392,986

(22) PCT Filed: Aug. 6, 2010
(86) PCT No.: PCT/EP2010/004835

§ 371 Date: Feb. 28, 2012

(30) Foreign Application Priority Data
Sep. 5, 2009 (EP) 09011 401.8

(51) Int. Cl. H01L 29/04; H01L 51/54; H01L 21/31

(52) U.S. Cl. 257/57; 438/780; 257/52; 438/99; 257/E21.24; 257/E29.003

(57) ABSTRACT

The present invention relates to solution processable passivation layers for organic electronic (OE) devices, and to OE devices, in particular organic field effect transistors (OFETs), comprising such passivation layers.

The present invention relates to solution processable passivation layers for organic electronic (OE) devices, and to OE devices, in particular organic field effect transistors (OFETs) and thin film transistors (TFTs), comprising such passivation layers.

### BACKGROUND OF THE INVENTION

An important aspect of manufacturing organic electronic devices or components, like for example organic transistors, organic solar cells, or backplanes of display devices featuring the driving electronics for individual pixels, is the fabrication technique when providing the individual functional layers of the device. Conventional manufacturing techniques are based on chemical vapor deposition and photolithography.

Today the development in the electronics industry goes towards replacing the expensive vacuum technology based processes with solution processable, printable technology. This new technology offers the advantages of avoiding the use of high vacuum equipment which reduces the cost of the process, allows the processes to be more easily scalable and extents the accessible size range of the display devices.

FIG. 1 shows schematically the key components of a single transistor of a display device backplane in a bottom gate configuration that was built using solution processable technology. Typically the manufacturing starts with a substrate (110) which can consist of glass, metal, or polymer. Onto the substrate (110) a metal gate electrode (120) is deposited by vapor deposition. Subsequently, a layer of a dielectric material (130) is deposited by techniques like spin coating or printing. This layer (130) is referred to as dielectric layer, or organic gate insulating (OGI) layer. Next a set of source and drain electrodes (150), also consisting of metal, are deposited. Finally a layer of organic semiconductor (OSC) (140) is formed covering the source drain electrodes (150) and the surface of the dielectric (130). Critical for the function of the device is an intact interface between the organic semiconductor layer (140) and the dielectric layer (130) in the region between the source and drain electrode, as indicated by the double arrow, which is also known as the “channel area”. Adhesion and maintaining a sharp interface are important aspects here.

Subsequently to forming this core part of the backplane, device manufactures usually add additional functional layers on top of the backplane and other devices. This requires further processing steps involving the use of reactive chemicals and solvents that in most cases would dissolve or damage the OSC or the interface between OSC and dielectric. The usual process strategy to avoid damaging the OSC is to deposit a protective layer (160) (also known as “passivation layer”) onto the OSC layer (140). Currently, display device manufacturers deposit SiO₂ or chemically resistant metals like gold by chemical vapor deposition in order to passivate the OSC.

The disadvantage of this approach is again the requirement for vacuum equipment and its involved limitations. The availability of solution processable passivation materials (SPPMs) is therefore desirable.

SPPMs have been described in prior art. For example, US 2005/0227407 A1 discloses a passivation multilayer comprising two or three subsequently deposited layers of organic materials. Those material combinations are either (a) polyvinyl alcohol (PVA) followed by polyvinyl phenol (PVP) or (b) PVA followed by PVP followed by polyimide (PI). Further disclosed is the deposition by different methods like spin coating, inkjet printing, screen printing and micro contact. It is also disclosed that the formulation for the passivation material can be an organic oil based solution, an inorganic water based solution, or a combination of both.

However, the use of polar and aqueous-based solvent systems can lead to ionic impurities in the electronic device, which will significantly reduce device performance.

WO2001/008241 A1 describes an OSC device with a barrier layer between functional layers at vulnerable interfaces inside the device, for example at the interface between the substrate and the gate electrode, between the OSC and the dielectric, or between the OSC and the source or drain electrode. The barrier layer can be a conductor, insulator or semiconductor. Suggested barrier layer materials include inorganic or organic materials like e.g. water soluble PVA, poly(meth)acrylates, polyurethanes, perylene, silicones or fluorinated species. However, there is no enabling disclosure how to provide a passivation layer on top of the device, or how to select suitable materials and methods for such a passivation layer.

US 2007/00776781 A1 discloses a process for the fabrication of active devices including OSCs, wherein the OSC layer and the OGI layer are formed by solution processing techniques, and the OGI layer may also be formed from an aqueous solution of PVA. However, passivation layers are not disclosed.

Besides, the documents cited above do neither discuss the problem of ionic impurities caused by solution processing from aqueous solutions and their negative influence on the device performance, nor do they suggest possible ways how to solve this problem.

It is an aim of the present invention to provide suitable methods and materials for preparing passivation layers on OE devices, in particular bottom gate (BG) OFETs and TFTs, by using solution processable passivation materials (SPPM). The passivation layers should be easily processable and should not or not significantly affect the device performance, like the on/off ratio and charge carrier mobility. They should protect the OE device against possible damage caused during later use or during subsequent device manufacturing process steps, in particular against inorganic acids, iodine and iodides, etchants, stripping agents, solvents, reactive additives, heat, humidity, oxygen, radiation like UV radiation, and mechanical stress. The preparation methods should not have the drawbacks of prior art methods and allow time-, cost- and material-effective production of OE devices at large scale. Other aims of the present invention are immediately evident to the expert from the following detailed description.

It was found that these aims can be achieved by providing methods and materials as claimed in the present invention.

### SUMMARY OF THE INVENTION

The invention relates to a process of preparing an organic electronic device, comprising the steps of

a) providing an organic semiconductor layer,
b) depositing a first passivation layer from a first formulation comprising a passivation material and one or more solvents onto the organic semiconductor layer and removing the solvents if present,
c) optionally depositing a second passivation layer from a second formulation comprising a passivation material and optionally one or more solvents onto the first passivation layer and removing the solvents if present,
wherein the solvents contained in the first formulation are selected from water or fluorinated organic solvents, and
wherein, if the first formulation comprises water as a solvent, the first formulation is treated to remove ionic impurities before deposition onto the organic semiconductor.

The invention further relates to an organic electronic (OE) device obtainable or obtained by a process as described above and below, in particular a top gate or bottom gate organic field effect transistor (OFET).

Preferably the OE device is selected from the group consisting of organic field effect transistors (OFET), thin film transistors (TFT), components of integrated circuitry (IC), radio frequency identification (RFID) tags, organic light emitting diodes (OLED), electroluminescent displays, flat panel displays, backlights, photodetectors, sensors, logic circuits, memory elements, capacitors, organic photovoltaic (OPV) cells, charge injection layers, Schottky diodes, planarising layers, antistatic films, conducting substrates or patterns, photoconductors, photoreceptors, electrophotographic devices and xerographic devices.

### BRIEF DESCRIPTION OF THE DRAWINGS

FIG. 1 schematically depicts a typical bottom gate, bottom contact OFET according to prior art.

FIG. 2 exemplarily and schematically depicts a bottom gate, bottom contact OFET according to the present invention.

FIG. 3 exemplarily and schematically depicts a bottom gate, top contact OFET according to the present invention.

FIG. 4 shows the transfer characteristics of an OFET prepared according to Example 2.

FIG. 5 shows the transfer characteristics of an OFET prepared according to Example 3.

FIG. 6 shows the transfer characteristics of an OFET prepared according to Example 4.

FIG. 7 shows the transistor mobility of an OFET prepared according to Example 5.

FIG. 8 shows the transfer current of an OFET prepared according to Example 5.

FIG. 9 shows the transistor mobility of an OFET prepared according to Example 6.

FIG. 10 shows the transfer current of an OFET prepared according to Example 6.

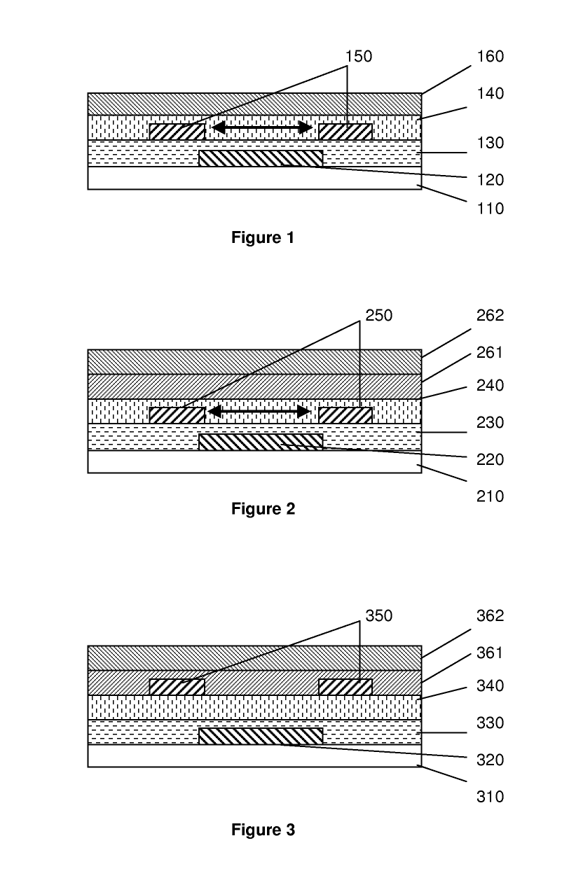

### DETAILED DESCRIPTION OF THE INVENTION

Above and below, the terms “dielectric” and “insulating” or “insulator” are used above and below interchangeably. Thus reference to an insulator layer also includes a dielectric layer and vice versa.

The area between the source electrode and the drain electrode in a transistor device is also referred to as the “channel area”.

The development of an SPPM is challenging for a variety of reasons. To one end the SPPM or its formulation has to be designed to be compatible with the underlying OSC and device architecture (orthogonality). Solution processable OSCs are in many cases soluble in a variety of organic solvents. Direct exposure of the OSC to those solvents should therefore be avoided. Furthermore, the adhesion of the OSC to the dielectric is of critical nature for the device function. The OSC and the dielectric will inevitably have different surface energies. This means that solvents that may not dissolve the OSC may still penetrate the OSC/dielectric interface and destroy the device functionality.

To the other end the SPPM has to fulfill a variety of function in terms of chemical resistance, in particular against materials and conditions applied in subsequent processing steps during device manufacture, for example when processing further functional layers by photolitograhic processes. A typical photolithographic process incudes one or more of the following processing steps, which may involve chemical and/or physical exposure of the underlying layers:
deposition of photo resists resin, typically in an organic solvent,
UV exposure,
development of the photo resists, typically using bases,
etching of metal, typically using aggressive acids and redox reactions,
removal of photo resists, typically using aggressive organic solvents.

The passivation material should also withstand both organic solvents and aqueous solutions. Contradictory to this requirement is that the passivation material has to be deposited at the same time from a solution which is typically either water or solvent based. To fulfill both requirements the passivation material may for example be cross-linked after deposition.

Another problem is that the passivation material has to subsequently withstand a range of very different conditions, which significantly reduces the choice of potentially suitable materials. For example the exposure to bases and acids may reverse cross-linking reactions or attack weak chemical bonds in the polymer backbone itself. As a consequence the polymer film may subsequently become water soluble or soluble in organic solvents and may not resist the exposure e.g. to photo resist strippers.

The following list includes some requirements for passivation materials and the typical problems to be solved when providing materials and methods for the preparation of passivation layers:
Chemical resistance: The passivation material should be chemically resistant to any chemicals that will be applied during subsequent processing steps. These chemicals can comprise water, polar/apolar/protic/aprotic solvents, acids, bases, ions and other reactive chemicals.
Physical resistance against radiation, sputtering, chemical vapor deposition, vacuum, drying by mechanical means, blow drying, temperature changes, mechanical stress caused by lifting of tools e.g. imprinting equipment.
Orthogonality I: The passivation material should be deposited onto the OSC without damaging the function of the transistor. This requires that the SPPM or the solvents in the formulation carrying the SPPM do not dissolve the OSC.
Orthogonality II: The interface between OSC and dielectric is critical for the function of the device. It was found that even solvents that do not dissolve the OSC can still creep into this interface, reduce adhesion and finally lift the OSC off the dielectric, thereby destroying the device.

The inventors of the present invention have found specific passivation materials and have developed novel and improved methods of applying these passivation materials, wherein these materials and methods meet the above mentioned requirements. It was found that by using the specific processes and SPPMs as described in the present invention the above-mentioned problems can be solved.

The passivation layer is preferably deposited from a formulation, which contains the SPPM material and optionally contains one or more solvents, co-solvents and/or surfactants. The SPPM itself preferably comprises a high molecular weight material, like polymers or oligomers, in order to prevent that the material itself could act as a solvent for the OSC. The SPPM is preferably an organic material, like an organic compound or a mixture of organic compounds.

An investigation of the impact of several solvents showed that water and fluorinated organic solvents do not deteriorate the device functionality and are therefore preferred, especially in the formulation use for deposition of the first passivation layer.

Thus, an orthogonal formulation used in the passivation process according to the present invention is preferably either water based or fluorinated solvent based. Another preferred formulation used in the passivation process, especially for depositing the second passivation layer, essentially consists, preferably 100%, of the active material without any solvents, wherein “active material” means the passivation material that forms the passivation layer after deposition and solvent removal.

It was also found that the performance of the device is influenced by the deposition of the passivation material, even when the most compatible formulations are used. For example a reduction of the transistor mobility can sometimes be observed when applying a passivation layer. By reducing the exposure or contact time of the SPPM formulation to the OSC, the performance of the passivated device can be improved and/or an eventual loss in performance caused by the passivation can be reduced. In one preferred embodiment of the present invention, a reduced contact time is achieved e.g. during spin coating deposition by using high speed and accelerations. In another preferred embodiment, additional heat treatment is applied to the passivation layer after deposition, to flash off the solvent(s) and to further reduce contact time to the OSC.

In some preferred embodiments the temperature is either increased or decreased during deposition of the passivation material. This can improve the performance of the passivated device and/or reduce an eventual loss in performance caused by the passivation.

Further studies showed that the exclusion of even low ion concentrations is critical for maintaining the functionality of the devices and is therefore preferred, especially when using water based formulations. Thus, in a preferred process according to the present invention, when using an SPPM that is an aqueous formulation, it is treated to remove ions, for example by dialysis, before deposition onto the OSC. This improves the device performance of the passivated device and/or reduces an eventual loss in performance caused by the passivation. This treatment to remove ionic impurities is especially preferred when using a passivation material which is consisting of or comprising a polyvinylalcohol or a derivative thereof, but can also be applied when using other passivation materials that are water soluble.

It was also found that the device performance after SPPM deposition can be further improved by lowering the concentration of the polymer in the formulation, especially in the formulation used for preparing the first passivation layer. This leads to a decrease of the SPPM layer thickness. Another preferred deposition process therefore comprises the following steps: A formulation with a low concentration of the SPPM, for example from 1 to 5%, preferably 2%, preferably an aqueous formulation, is deposited for example by spin coating. A second layer of a formulation with a higher concentration of the same SPPM material and preferably the same solvent(s), for example from 5 to 15%, preferably 10%, preferably an aqueous formulation, is deposited immediately afterwards. Both deposited layers are then cured by heating the substrate. The device performance thereby achieved is superior to a direct deposition of the higher concentrated formulation. At the same time the desired passivation layer thickness is maintained.

The passivation layer according to the present invention is preferably a continuous film. The thickness of the first passivation layer is preferably from 20 nm to 5 μm, very preferably from 20 nm to 2 μm, most preferably from 500 nm to 1.5 μm. The thickness of the second passivation layer is preferably from 1 μm to 25 μm, very preferably from 5 to 20 μm, most preferably from 10 μm to 14 μm. A thickness of approx. 12 μm has been shown to be especially suitable and preferred. Unless stated otherwise, the film thickness values given above and below refer to the dried film after solvent removal and annealing or curing steps. Preferably the passivation layer covers the exposed surfaces of the OE device.

The passivation layer according to the present invention is preferably a multilayer consisting of two or more, preferably two single layers.

The first layer (“orthogonal layer”) comprises a passivation material which is preferably chemically orthogonal to the exposed parts of the device, in particular the OSC. The formulation which is used to deposit the passivation material, including all solvents, is preferably also chemically orthogonal to the exposed parts of the device.

“Chemically orthogonal” means that the exposed parts of the device remain chemically and physically unaltered when being brought into contact with the passivation material or its formulation.

“Chemically unaltered” means that no material or component of the device, for example the OSC, diffuses into the passivation material, which could lead to dissolution of the device, and that no component of the passivation material or the SPPM formulation (for example metal ions like Li, Na, K, Ca, small molecules, or transition metals, especially noble metals, that could coordinate to the OSC) diffuses into the device, especially into the OSC layer. “Physically unaltered” means that the device remains physically intact, and that there is no deformation or penetration of the interface between the dielectric and the OSC.

The orthogonal layer preferably comprises a polymer, oligomer, or polymerisable material that is chemically orthogonal to the device, especially to the OSC layer. The orthogonal layer is preferably deposited from a chemically orthogonal formulation. These include aqueous formulations, formulations comprising fluorinated solvents, and formulations consisting essentially 100% of active material.

In a preferred embodiment, the orthogonal layer comprises a water soluble polymer, oligomer, or polymerisable material that is chemically orthogonal to the device, especially the OSC material, and is deposited from an aqueous formulation as described above and below.

In another preferred embodiment, the orthogonal layer comprises a fluorinated polymer, oligomer, or polymerisable material that is chemically orthogonal to the device, especially the OSC material, and is deposited from a fluorinated formulation as described above and below.

The orthogonal layer may also consist of an essentially 100% active components material that is deposited from a formulation as described above and below.

The second layer (“protective layer”) provides improved chemical and physical resistance against and protection against possible damage caused by any subsequent processing steps or conditions.

The protective layer is preferably applied when a higher chemical resistance is required than the orthogonal layer can provide.

The protective layer comprises for example a polymer, oligomer, or polymerisable material that on cure resists process chemicals as described above and below. The protective layer is preferably deposited from a formulation as described above and below. These include aqueous formulations, formulations comprising fluorinated solvents, formulations consisting essentially of 100% active material, and formulations comprising polar organic sovents.

The charge carrier mobility of the device after passivation is preferably 50%, very preferably 70% of the initial value before passivation. The on/off ratio of the device after passivation is preferably 50%, preferably 90% of the initial value before passivation.

Preferably the passivation layer, very preferably at least the first passivation layer, comprises, very preferably consists of, an insulating material with a resistance greater than 10¹⁴ Ω·cm².

In another preferred embodiment of the present invention, if the processing chemicals or conditions utilised in subsequent processing or device manufacturing steps are sufficiently moderate in order for the orthogonal passivation layer to withstand these chemicals or conditions, a second, protective passivation layer is not required. In this embodiment the orthogonal layer does at the same time serve as protective layer, so that the passivation layer is a monolayer providing both orthogonal and protective functions.

The passivation process according to the present invention is designed to protect the semiconductor device, especially the OSC, against possible damage caused by any subsequent processing steps or conditions, for example vacuum or solution processing steps, during manufacture, and from any potential exposure during its intended use. These processing steps and conditions include, without limitation:
Vacuum processing steps, including but not limited to
   exposure to vacuum, radiation and deposition of matter,
   stress on the device, especially on the surface as a result of vacuum,
   evaporation, condensation, sublimation, or re-sublimation occurring on the device,
   sputter coating or chemical vapor deposition,
   irradiation for example by electron beams or UV light,
   vacuum deposition of materials like for example ITO or metals like copper, silver, gold, silver, palladium, platinum, rhodium, iridium, ruthenium, osmium, aluminium, chromium, titania, nickel;
Mechanical stress caused by lifting of tools, e.g. imprinting equipment;
Temperature changes;
Drying steps for example by air flow or mechanical contacting means,
Solution processing steps, including but not limited to
   deposition of photo-resists,
   solvent exposure for example to alcohols, aliphatic and aromatic hydrocarbons, glycols, ketenes, olefins, alkenes, halo alkenes, halo aromatics,
   development of photo resist layers with bases including sodium hydroxide, potassium hydroxide, calcium hydroxide, ammonium hydroxide, alkylated ammonium hydroxide, pyridine, imidazole, benzimidazole, phosphazene,
   chemical etchants like acids and redox reagents including, without limitation, phosphoric acid, nitric acid, ferric nitrate, hydrochloric acid, acetic acid, sulphuric acid, iodide/iodine, hydrobromic acid, perchloric acid, chromic acid, methanesulfonic acid, ethanesulfonic acid, benzenesulfonic acid, toluenesulfonic acid, citric acid or formic acid,
   stripping of a photo resist layer by chemicals like for example N-methylpyrrolidone, 2-pyrrolidone, 1,3-Dimethyl-2-imidazolidinone, dimethyl formamide, dimethyl sulfoxide, dimethyl acetamide, 1,4-dioxane, tetra-hydrofuran, ethylene glycol monomethyl ether, ethylene glycol monoethyl ether, ethylene glycol monopropyl ether, ethylene glycol monoisopropyl ether, ethylene glycol monobutyl ether, ethylene glycol monophenyl ether, ethylene glycol monobenzyl ether, diethylene glycol monomethyl ether, diethylene glycol monoethyl ether, diethylene glycol mono-n-butyl ether, ethylene glycol dimethyl ether, ethylene glycol diethyl ether, ethylene glycol dibutyl ether, ethylene glycol methyl ether acetate, ethylene glycol monoethyl ether acetate, ethylene glycol monobutyl ether acetate and mixtures of the aforementioned,
   resistance against environmental influences such as moisture or corrosion.

Some preferred embodiments related to specific materials and processes according to the present invention are described in the following.

Preferably the SPPM layers are deposited from formulations. The formulations can be aqueous based, solvent based, fluorinated solvent based, or consist of, preferably essentially 100%, active compounds. In addition to the SPPM, the formulations can comprise one or many additional components for example selected from resins, polymers, oligomers, monomers, solvents, cross-linking agents, photoinitiators, catalysts, biocides, spherical particles or plate like particles, for example inorganic flakes as described in WO 2005/035672 A1.

The ion content in the final formulation should be as low as possible. The conductivity of the formulation is preferably ≦500 μS cm⁻¹, very preferably ≦50 μS cm⁻¹.

In order to reduce the ion content in the formulation one of the following purification methods is preferably used: Dialysis, reverse osmosis, ultrafiltratrion, microfiltration, nanofiltration, or other known methods to remove small molecules and ions from solutions.

In case of aqueous formulations, these can be real solutions (1-phase), dispersions, suspensions, or any other 2-phase system. The term “aqueous” include, without limitation, 100% water, preferably d.i. (de-ionized) water, mixtures of water with alcohols, mixtures of water with ketones, mixtures of water with glycols, and mixtures of water and ethers. Preferably the solvent consists to more than 80% of water, and the co-solvents are more volatile than water.

Aqueous formulations preferably comprise one or more of the following compounds as passivation material: Water soluble resins, polymers, oligomers, polymer precusors or polymerisable materials, including mixtures of any of the aforementioned.

Suitable and preferred examples of water soluble passivation materials include, without limitation, the materials listed below:
Modified poly-(vinyl alcohol), like for example Kuraray Exceval AQ-4104, Kuraray Exceval HR-3010, Kuraray Exceval RS-1113, Kuraray Exceval RS-1117, Kuraray Exceval RS-1713, Kuraray Exceval RS-1717, Kuraray Exceval RS-2117, Kuraray Exceval RS-2817 SB, polyvinylpyrrolidone, like for example ISP K-12, ISP K-15, ISP K-30, ISP K-60, ISP K-85, ISP K-90, ISP K-120, ISP ViviPrint 540,
amino resins like urea formaldehyde, melamine formaldehyde, benzoguanamine formaldehyde or carbamate. Examples include, without limitation, BASF Luwipal 063, BASF Luwipal 066, BASF Luwipal 066, BASF Luwipal 068, BASF Luwipal 069, BASF Luwipal 072 BASF Luwipal 073, BASF Luwipal LR 8955, BASF Luwipal 052, BASF Plastopal BTM, BASF Plastopal BTM, Cytec CYMEL® 301, Cytec CYMEL 303 LF, Cytec CYMEL 350, Cytec CYMEL 3745, Cytec CYMEL MM-100, Cytec Cymel UM-15, Cytec CYMEL® 370, Cytec CYMEL 373, Cytec CYMEL 3749, Cytec CYMEL® 323, Cytec CYMEL 325, Cytec CYMEL 327, Cytec CYMEL 328, Cytec CYMEL 385,
acrylic copolymers, like for example DSM NeoResins+NeoCryl A081W, DSM NeoResins+NeoCryl A1127, DSM NeoResins+NeoCryl BT20, DSM NeoResins+NeoCryl FL711, DSM NeoResins+NeoCryl BT26, DSM NeoResins+NeoCryl BT36, DSM NeoResins+NeoCryl BT24, DSM NeoResins+NeoCryl BT27,
acrylic/styrene copolymers, like e.g. DSM NeoResins+NeoCryl XK62, DSM NeoResins+NeoCryl XK63, DSM NeoResins+NeoCryl XK64, DSM NeoResins+NeoCryl XK85, DSM NeoResins+NeoCryl XK101, DSM NeoResins+NeoCryl XK166, DSM NeoResins+NeoCryl XK176, DSM NeoResins+NeoCryl A633, DSM NeoResins+NeoCryl A639, DSM NeoResins+NeoCryl A662, DSM NeoResins+NeoCryl A667, DSM NeoResins+NeoCryl XK12, DSM NeoResins+NeoCryl XK16, DSM NeoResins+NeoCryl AF10, DSM NeoResins+NeoCryl FL375,
water soluble fluoropolymers, like for example Asahi Glass FE 4300, Asahi Glass FE 4400,
anionic polyesters, like for example (DSM NeoResins+ NeoRez R2005,
acrylic/urethane copolymers, like for example DSM NeoResins+NeoRad R440, DSM NeoResins+NeoRad R 441, DSM NeoResins+NeoRad R447, DSM NeoResins+NeoRad R448, DSM NeoResins+NeoRad R450, DSM NeoResins+Neo Pac E 180, DSM NeoResins+Neo PacE 106, DSM NeoResins+Neo Pac E 129, Air Products HB 870, Air Products HB 878,
polycarbonate/urethane copolymers, like for example DSM NeoResins+ NeoRez R986),
polyurethane, like for example DSM NeoResins+NeoRez R 1010,
norbornene polymers or norbornene derived polymers.

Suitable and preferred cross-linking agents include, without limitation, 40% aqueous glyoxal, polyisocyanates like Bayer Byhydur BH305, BH3100, aziridine like CX100 DSM NeoResins+, carbodiimide like Zoldine XL29SE (Dow Chemicals) or CX300 DSM NeoResins+.

Suitable and preferred catalysts include, without limitation, p-toluene sulfonic acid, isomers thereof and derivates thereof. Examples include Cytec CYCAT 500, Cytec CYCAT 600, Cytec CYCAT 4040, Cytec CYCAT 296-9, Cytec CYCAT XK 350, Cytec CYCAT VXK 6378 N.

Suitable and preferred photoinitiators include, without limitation, 2-Hydroxy-4′-(2-hydroxyethoxy)-2-methylpropiophenone.

Suitable and preferred biocides include, without limitation, 1,2-Benzisothiazol-3(2H)-one (Aldrich), 2-bromo-2-nitropropane-1,3-diol (Aldrich).

Suitable and preferred spherical particles include, without limitation, silica particles and modified silica particles, for example Grace Ludox AS-30, Grace Ludox AS-40, Grace Ludox SM-AS, Grace Ludox AM, Grace Ludox HAS, Grace Ludox TMA, Grace Ludox CL, Grace Ludox CL-P, Grace Ludox FM, Grace Ludox SM, Grace Ludox HS-30, Grace Ludox HS-40, Grace Ludox LS, Grace Ludox TM-40, Grace Ludox TM-50, Grace Ludox P X-30, Grace Ludox P T-40, Grace Ludox P W-50), fluorinated particles.

Suitable and preferred plate like particles include, without limitation, synthetically produced clay (Rockwood Laponite), Bentonite clay (Rockwood Bentolite, Rockwood Claytone), magnesium aluminum silicate platelets (Rockwood Cloisite and Nanofil), smectite clays (Rockwood Fulacolor, Rockwood Permont, Fulcat), mica and modified mica (Merck Iriodine), silica platelets (Merck Colorstream), aluminium oxide/titanium oxide (Merck Xirallic), synthetic borosilicate flakes (Merck Miraval), bismuth oxychloride crystal platelets (Merck Biflair), glass flakes (window glass, A glass, C glass, E glass, ECR glass, Duran glass, laboratory apparatus glass, optical glass, quartz glass).

Fluorinated solvent based formulations, especially for the first passivation layer, preferably comprise one or more of the following compounds as passivation material: Fluorinated hydrocarbon polymers, oligomers, polymer precusors or polymerisable materials, including mixtures of any of the aforementioned.

Suitable and preferred examples of fluorinated hydrocarbon passivation materials include, without limitation, Dupont Teflon AF, Asahi Glass Cytop, for example Cytop 809®, PTFE, FEP, PFA, PCTFE, ETFE, ECTFE, PVDF, Solvey Hyflon AD60, Solvey Hyflon AD 80, DuPont Teflon AF 1600, DuPont Teflon AF 2400, DuPont Nafion.

Suitable and preferred examples of fluorinated solvents include, without limitation, 3M FC40, 3M FC43, 3M FC70, 3M FC72, 3M FC77, 3M FC84, 3M FC87, 3M FC3283, 3M Novec 7000, 3M Novec 7100, 3M Novec 7200, 3M Novec 7500, Fluorochem Perfluoroperhydrofluorene, Fluorochem Perfluoro(methyldecalin), Fluorochem Perfluoroperhydrophenanthrene, Solvay Solvay Galden HT-200, Solvay Solvay Galden HT-230, Solvay Solvay Galden HT-250.

Formulations for the second passivation layer preferably consist of, very preferably essentially 100%, active material. Such formulations preferably consist of one or more compounds selected from polymers, oligomers, polymer precusors or polymerisable materials, including mixtures of any of the aforementioned. In addition they can optionally contain one or more additives selected from cross-linkers and catalysts.

Suitable and preferred polymers, oligomers and polymerisable materials for the second passivation layer include the following:
Functional silicone polymers or resins which have for example one or more vinyl functional groups. Suitable and preferred examples include, without limitation, DOW CORNING SYL-OFF 7681-030, DOW CORNING SYL-OFF 7010, DOW CORNING SYL-OFF 7040, DOW CORNING SYL-OFF 7044, DOW CORNING SYL-OFF 7395, DOW CORNING SYL-OFF 7600, DOW CORNING SYL-OFF 7610, DOW CORNING SYL-OFF 7671, DOW CORNING SYL-OFF 7673, DOW CORNING SL 400, Wacker CRA 17, Wacker Dehesive 920, Wacker Dehesive 991, Fluoro Chem PDV 0525, Fluoro Chem PDV 1625, Gelest Gel D200, Gelest D300, Gelest P065, Gelest F065, Gelest OE41, Gelest OE42, Gelest OE43, Gelest RG01, Gelest RG02,
polymers, oligomers, or polymerisable materials that have both alkoxy silicone and aliphatic epoxy functionalities, like for example Evonik Silikopon EF,
moisture activated, low viscosity, solvent-free polydimethylsiloxanes, like for example Gelest Zipcone CG,
polymers, oligomers or polymerisable materials based on a vinyllactam-polyacrylate copolymer, like for example International Speciality Products Gafgard.

Suitable and preferred cross-linking compounds are for example organoreactive silane cross-linkers such as hydrogenpolysiloxane containing a high percentage of reactive Si—H, for example DOW SYL-OFF 7682, Wacker V24, or amino alkoxy silane cross-linking compounds, like for example Evonik Dynasylan AMEO, Evonik Dynasylan AMMO.

Suitable and preferred catalysts include highly active platinum complexes that aid the thermal curing of addition cross-linking, the wt. % of platinum in these being for example circa 0.115%, for example Dow Corning Syl-Off 4000, Wacker OL.

The formulations may also contain volatile components or diluents, which are not deliberately added but can be present in the formulation for example as a result of previous production and processing steps, or as residues from the chemical manufacture of the formulation or its components, including but not limited to starting materials, solvents used for synthesis or purification, etc. If such diluents or volatile components are present, their maximum concentration in the formulation is preferably 5% or less, very preferably 3% or less, more preferably 1% or less, most preferably 0%.

Another preferred embodiment of the present invention relates to organic solvent based formulations, especially for the second passivation layer, comprising one or more polar solvents selected from alcohols, ketons, ketones, ester, amides, lactones, lactams, glycols, glycol ethers and mixtures of those.

Suitable and preferred examples of polar solvents include methanol, ethanol, propanol, n-butanol, iso-propanol, iso-butanol, 2-butoxy ethanol, acetone, glycerol, ethylene glycol monomethyl ether, ethylene glycol monoethyl ether, ethylene glycol monopropyl ether, ethylene glycol monoisopropyl ether, ethylene glycol monobutyl ether, ethylene glycol monophenyl ether, ethylene glycol monobenzyl ether, diethylene glycol monomethyl ether, diethylene glycol monoethyl ether, diethylene glycol mono-n-butyl ether, ethylene glycol dimethyl ether, ethylene glycol diethyl ether, ethylene glycol dibutyl ether, ethylene glycol methyl ether acetate, ethylene glycol monethyl ether acetate, ethylene glycol monobutyl ether acetate.

Solvent based formulations of this embodiment preferably comprise of one or more compounds selected from resins, polymers, oligomers, polymer precusors or polymerisable materials, or mixtures of any of the aforementioned, which are soluble in the polar solvents.

Examples of suitable and preferred compounds include the following:
Norbornene polymers or norbornene derived polymers,
amino resins like for example urea formaldehyde, melamine, formaldehyde or enzoguanamine formaldehyde. Example include, without limitation, CYTEC CYMEL 202, CYTEC CYMEL 203, CYTEC CYMEL 254, CYTEC CYMEL 1125, CYTEC CYMEL 1141, CYTEC CYMEL MB-11-B, CYTEC, CYMEL MB-14-B, CYTEC CYMEL 683, CYTEC CYMEL 688, CYTEC CYMEL 1158, CYTEC CYMEL MI-12-I, CYTEC CYMEL MI-97-IX, CYTEC CYMEL U-80, CYTEC CYMEL UB-25-BE, CYTEC CYMEL UB-30-B, CYTEC CYMEL U-646, CYTEC CYMEL U-663, CYTEC CYMEL U-665, CYTEC UI-19-I, CYTEC CYMEL UI-19-IE, CYTEC CYMEL LA-20-E, CYTEC CYMEL UI-38-I, CYTEC CYMEL 1170.

A particularly preferred SPPM formulation for the first passivation layer, which provides very good orthogonality to the OSC layer, comprises a fluorinated polymer, for example Teflon AF 1600 or Teflon AF 2400 (from DuPont), or Cytop-809M (from Ashai Glass) and a fluorinated solvent, like for example FC43 or FC70 (from 3M). Under ideal conditions no performance loss on SPPM deposition was found when using such a formulation for preparing the first passivation layer.

Another particularly preferred SPPM formulation for the first passivation layer, which provides very good orthogonality to the OSC layer, comprises an aqueous solution of a hydrophobically modified polyvinylalcohol, for example ethylene modified poly-(vinyl alcohol) like Exceval HR3010 from Kuraray, which is preferably dialysed before deposition in order to remove ions. The material is preferably cross-linked with a cross-linker after deposition. For this purpose a cross-linker, for example aqueous glyoxal, for example as 40% aqueous solution, is added to the formulation preferably before deposition. This preferred formulation is not only orthogonal to the OSC, but also exhibits good chemical resistance against organic solvents and moderate chemical resistance against water. It can therefore also be used for a monolayer embodiment as described above, which contains only a single passivation layer that serves both as orthogonal and protective layer.

A particularly preferred SPPM formulation for the second passivation layer, which provides very good chemical resistance, is an essentially 100% active components based silicon material, for example DOW SYL-OFF 7681-030 with cross-linker 7682 and catalyst 4000.

Another particularly preferred SPPM formulation for the second passivation layer, which provides good chemical resistance, comprises a urea formaldehyde amino resin, for example Cytec Cymel UI20E in a suitable solvent, for example an alcohol or a mixture of an alcohol and a ketone, like a mixture of butanone and butanol, or Cytec Cymel UM-15 in water, and preferably further comprises one or more additives selected from rheology modifiers and wetting agents.

In the process according to the present invention, the passivation material can be applied to the substrate as a formulation by known methods, including but not limited to ink jet printing, dip coating, spin coating, flexo printing, gravure printing, screen printing, curtain coating, or other traditional printing, or printing and coating, techniques.

To maintain the device performance after deposition of the SPPM for the first passivation layer, the contact time and level of interaction between the OSC and the SPPM formulation should preferably be minimised. Suitable and preferred methods for minimising contact time and interaction levels include the following:
Reducing the contact time by speed coating at high speed with high acceleration. For spin coating of the orthogonal layer suitable and preferred speeds are for example between 500 and 5000 rpm at accelerations between 1000 and 6000 rpm/s;
Reducing the interactions by increasing or decreasing the temperature of the formulation. For the deposition of a fluorinated orthogonal layer formulation for example a temperature of or around 5° C., for an aqueous formulation a temperature of or around 20° C. is suitable;
Reducing the interactions by changing the viscosity or concentration of the formulation. For example in case of an aqueous PVA formulation, PVA concentrations below 5%, especially of or around 2% are preferred;
Coating with a low concentration formulation followed by a higher concentration formulation, as described above.

After deposition, any solvents present in the formulation are preferably removed, for example by evaporation, which can be accelerated by raising the temperature for example to or above a temperature of 100° C., and/or by reducing the pressure.

In another preferred embodiment of the present invention, the passivation layer material of the first and/or second passivation layer is cross-linked after deposition, for example by drying, thermal cure, or radiation cure.

The passivation layers according to the present invention can be used to maintain the integrity and function of any solution processable electronic devices during their intended application or further liquid processing stages, especially photolithographic processes like solvent exposure, etching stages, spin coating, printing, developing, or curing stages.

Especially preferred are solution processable semiconductor devices or diodes, in particular solution processable organic semiconductor devices or organic diodes. The passivation layers can especially be used for device manufacturing by solution processing of n- or p-type bottom gate transistor devices with top or bottom contact, in particular wherein the semiconductor comprises an organic material. Especially preferred devices are OFETs and organic TFTs.

FIG. 2 is a schematic representation of a BG, bottom contact OFET according to the present invention, including a gate electrode (220) provided on a substrate (210), a layer of dielectric material (230) (gate insulator layer), source (S) and drain (D) electrodes (250), a layer of OSC material (240), a first passivation layer (261) with orthogonal function towards the OSC layer, and a second passivation layer (262) with protective function towards the OSC layer and the other device layers, for example against damage caused by further processing steps or environmental influence.

FIG. 3 is a schematic representation of a typical BG, top contact OFET according to prior art, including a gate electrode (320) provided on a substrate (310), a layer of dielectric material (330) (gate insulator layer), source (S) and drain (D) electrodes (350), a layer of OSC material (340), a first passivation layer (361) with orthogonal function towards the OSC layer, and a second passivation layer (362) with protective function towards the OSC layer and the other device layers.

Preferably the deposition of the other functional layers of the OE device, like the OSC layer and the gate insulator layer, is carried out using solution processing techniques. This can be done for example by applying a formulation, preferably a solution, comprising the OSC or dielectric material, respectively, and further comprising one or more organic solvents, onto the previously deposited layer, followed by evaporation of the solvent(s). Preferred deposition techniques include, without limitation, dip coating, spin coating, ink jet printing, letter-press printing, screen printing, doctor blade coating, roller printing, reverse-roller printing, offset lithography printing, flexographic printing, web printing, spray coating, brush coating, or pad printing. Very preferred solution deposition techniques are spin coating, flexographic printing and inkjet printing.

Preferably the insulator layer is deposited by solution processing, very preferably using a solution of the dielectric material in one or more organic solvents. Preferably the dielectric material and the OSC material, and the respective solvents used for their deposition, are chemically orthogonal to each other. The dielectric material may also be cross-linkable and/or contain a cross-linkable component or additive.

Suitable solvents are selected from hydrocarbon solvents, aromatic solvents, cycloaliphatic cyclic ethers, cyclic ethers, acetated, esters, lactones, ketones, amides, cyclic carbonates or multi-component mixtures of the above. Examples of preferred solvents include cyclohexanone, mesitylene, xylene, 2-heptanone, toluene, tetrahydrofuran, MEK, MAK (2-heptanone), cyclohexanone, 4-methylanisole, butyl-phenyl ether and cyclohexylbenzene, very preferably MAK, butyl phenyl ether or cyclohexylbenzene.

The total concentration of the respective functional material in the formulation is preferably from 0.1 to 30 wt. %, preferably from 0.1 to 5 wt. %. In particular organic ketone solvents with a high boiling point are advantageous for use in solutions for inkjet and flexographic printing.

When spin coating is used as deposition method, the OSC or dielectric material is spun for example between 1000 and 2000 rpm for a period of for example 30 seconds to give a layer with a typical layer thickness between 0.5 and 1.5 μm. After spin coating the film can be heated at an elevated temperature to remove all residual volatile solvents.

If a cross-linkable dielectric material is used, it is preferably exposed to electron beam or electromagnetic (actinic) radiation after deposition, like for example X-ray, UV or visible radiation. For example, actinic radiation can used having a wavelength of from 50 nm to 700 nm, preferably from 200 to 450 nm, most preferably from 300 to 400 nm. Suitable radiation dosages are typically in the range from 25 to 3,000 mJ/cm². Suitable radiation sources include mercury, mercury/xenon, mercury/halogen and xenon lamps, argon or xenon laser sources, x-ray, or e-beam. The exposure to actinic radiation will induce a cross-linking reaction in the cross-linkable groups of the dielectric material in the exposed regions. It is also possible for example to use a light source having a wavelength outside the absorption band of the cross-linkable groups, and to add a radiation sensitive photosensitizer to the cross-linkable material.

Optionally the dielectric material layer is annealed after exposure to radiation, for example at a temperature from 70° C. to 130° C., for example for a period of from 1 to 30 minutes, preferably from 1 to 10 minutes. The annealing step at elevated temperature can be used to complete the cross-linking reaction that was induced by the exposure of the cross-linkable groups of the dielectric material to photoradiation.

All process steps described above and below can be carried out using known techniques and standard equipment which are described in prior art and are well-known to the skilled person. For example, in the photoirradiation step a commercially available UV lamp and photomask can be used, and the annealing step can be carried out in an oven or on a hot plate.

The thickness of the functional layers, other than the passivation layers, in an OE device according to the present invention is preferably from 1 nm (in case of a monolayer) to 10 μm, very preferably from 1 nm to 1 μm, most preferably from 5 nm to 500 nm.

Various substrates may be used for the fabrication of OE devices, for example glass or plastics, plastics materials being preferred, examples including alkyd resins, allyl esters, benzocyclobutenes, butadiene-styrene, cellulose, cellulose acetate, epoxide, epoxy polymers, ethylene-chlorotrifluoro ethylene, ethylene-tetra-fluoroethylene, fibre glass enhanced plastic, fluorocarbon polymers, hexafluoropropylenevinylidene-fluoride copolymer, high density polyethylene, parylene, polyamide, polyimide, polyaramid, polydimethylsiloxane, polyethersulphone, poly-ethylene, polyethylenenaphthalate, polyethyleneterephthalate, polyketone, polymethylmethacrylate, polypropylene, polystyrene, polysulphone, polytetrafluoroethylene, polyurethanes, polyvinylchloride, silicone rubbers, and silicones.

Preferred substrate materials are polyethyleneterephthalate, polyimide, and polyethylenenaphthalate. The substrate may be any plastic material, metal or glass coated with the above materials. The substrate should preferably be homogeneous to ensure good pattern definition. The substrate may also be uniformly pre-aligned by extruding, stretching, rubbing or by photochemical techniques to induce the orientation of the organic semiconductor in order to enhance carrier mobility.

The electrodes can be deposited by liquid coating, such as spray-, dip-, web- or spin-coating, or by vacuum deposition or vapor deposition methods. Suitable electrode materials and deposition methods are known to the person skilled in the art. Suitable electrode materials include, without limitation, inorganic or organic materials, or composites of the two.

Examples for suitable conductor or electrode materials include polyaniline, polypyrrole, PEDOT or doped conjugated polymers, further dispersions or pastes of graphite or particles of metal such as Au, Ag, Cu, Al, Ni or their mixtures as well as sputter coated or evaporated metals such as Cu, Cr, Pt/Pd or metal oxides such as indium tin oxide (ITO). Organometallic precursors may also be used deposited from a liquid phase.

The OSC materials and methods for applying the OSC layer can be selected from standard materials and methods known to the person skilled in the art, and are described in the literature.

In case of OFET devices, where the OFET layer is an OSC, it may be an n- or p-type OSC, which can be deposited by vacuum or vapor deposition, or preferably deposited from a solution. Preferred OSCs have a FET mobility of greater than 1×10⁻⁵ cm²V⁻¹s⁻¹.

The OSC is used for example as the active channel material in an OFET or a layer element of an organic rectifying diode. OSCs that are deposited by liquid coating to allow ambient processing are preferred. OSCs are preferably spray-, dip-, web- or spin-coated or deposited by any liquid coating technique. Ink-jet deposition is also suitable. The OSC may optionally be vacuum or vapor deposited.

The semiconducting channel may also be a composite of two or more of the same types of semiconductors. Furthermore, a p-type channel material may, for example be mixed with n-type materials for the effect of doping the layer. Multilayer semiconductor layers may also be used. For example the semiconductor may be intrinsic near the insulator interface and a highly doped region can additionally be coated next to the intrinsic layer.

The OSC may be a monomeric compound (or “small molecule”, in contrast to a polymer or macromolecule), an oligomer or a polymer, or a mixture, dispersion or blend containing one or more compounds selected from either or both of small molecules and polymers.

In case of monomeric compounds, the OSC is preferably a conjugated aromatic molecule, and contains preferably at least three aromatic rings. Preferred monomeric OSCs contain 5, 6 or 7 membered aromatic rings, and more preferably contain 5 or 6 membered aromatic rings.

Each of the aromatic rings optionally contains one or more hetero atoms selected from Se, Te, P, Si, B, As, N, O or S, preferably from N, O or S.

The aromatic rings may be optionally substituted with alkyl, alkoxy, polyalkoxy, thioalkyl, acyl, aryl or substituted aryl groups, halogen, particularly fluorine, cyano, nitro or an optionally substituted secondary or tertiary alkylamine or arylamine represented by —N(R³)(R⁴), where R³ and R⁴ each independently is H, optionally substituted alkyl, optionally substituted aryl, alkoxy or polyalkoxy groups. Where R³ and R⁴ is alkyl or aryl these may be optionally fluorinated.

The rings may be optionally fused or may be linked with a conjugated linking group such as —C(T¹)=C(T²)-, —C≡C—, —N(R′)—, —N═N—, (R′)═N—, —N═C(R′)—. T¹ and T² each independently represent H, Cl, F, —C≡N or lower alkyl groups particularly C₁₋₄ alkyl groups; R′ represents H, optionally substituted alkyl or optionally substituted aryl. Where R′ is alkyl or aryl these may be optionally fluorinated.

Further preferred OSC compounds include compounds, oligomers and derivatives of compounds selected from the group comprising conjugated hydrocarbon polymers such as polyacene, polyphenylene, poly(phenylene vinylene), polyfluorene including oligomers of those conjugated hydrocarbon polymers; condensed aromatic hydrocarbons such as tetracene, chrysene, pentacene, pyrene, perylene, coronene, or soluble, substituted derivatives of these; oligomeric para substituted phenylenes such as p-quaterphenyl (p-4P), p-quinquephenyl (p-5P), p-sexiphenyl (p-6P), or soluble substituted derivatives of these; conjugated heterocyclic polymers such as poly(3-substituted thiophene), poly(3,4-bisubstituted thiophene), optionally substituted polythieno[2,3-b]thiophene, optionally substituted polythieno[3,2-b]thiophene, poly(3-substituted selenophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, polyisothianaphthene, poly(N-substituted aniline), poly(2-substituted aniline), poly(3-substituted aniline), poly(2,3-bisubstituted aniline), polyazulene, polypyrene; pyrazoline compounds; polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines or fluoronaphthalocyanines; C₆₀ and C₇₀ fullerenes; N,N′-dialkyl, substituted dialkyl, diaryl or substituted diaryl-1,4,5,8-naphthalenetetracarboxylic diimide and fluoro derivatives; N,N′-dialkyl, substituted dialkyl, diaryl or substituted diaryl 3,4,9,10-perylenetetracarboxylicdiimide; bathophenanthroline; diphenoquinones; 1,3,4-oxadiazoles; 11,11,12,12-tetracyanonaptho-2,6-quinodimethane; α,α′-bis(dithieno[3,2-b2′,3′-d]thiophene); 2,8-dialkyl, substituted dialkyl, diaryl or dialkynyl anthradithiophene; 2,2′-bibenzo[1,2-b:4,5-b′]dithiophene. Preferred compounds are those from the above list and derivatives thereof which are soluble in organic solvents.

Especially preferred OSC compounds are polymers or copolymers comprising one or more repeating units selected from thiophene-2,5-diyl, 3-substituted thiophene-2,5-diyl, optionally substituted thieno[2,3-b]thiophene-2,5-diyl, optionally substituted thieno[3,2-b]thiophene-2,5-diyl, selenophene-2,5-diyl, or 3-substituted selenophene-2,5-diyl.

Further preferred OSC compounds are substituted oligoacenes such as pentacene, tetracene or anthracene, or heterocyclic derivatives thereof, like 6,13-bis(trialkylsilylethynyl) pentacene or 5,11 bis(trialkylsilylethynyl) anthradithiophene, which are optionally further substituted, as disclosed for example in U.S. Pat. No. 6,690,029, WO 2005/055248 A1 or U.S. Pat. No. 7,385,221.

In another preferred embodiment of the present invention the OSC layer comprises one or more organic binders to adjust the rheological properties as described for example in WO 2005/055248 A1, in particular an organic binder which has a low permittivity ∈ at 1,000 Hz of 3.3 or less.

The binder is selected for example from poly(α-methylstyrene), polyvinylcinnamate, poly(4-vinylbiphenyl) or poly(4-methylstyrene, or blends thereof. The binder may also be a semiconducting binder selected for example from polyarylamines, polyfluorenes, polythiophenes, polyspirobifluorenes, substituted polyvinylenephenylenes, polycarbazoles or polystilbenes, or copolymers thereof. A preferred dielectric material (3) for use in the present invention preferably comprises a material with a low permittivity of between 1.5 and 3.3 at 1000 Hz, such as for example Cytop™809m available from Asahi Glass.

Unless the context clearly indicates otherwise, as used herein plural forms of the terms herein are to be construed as including the singular form and vice versa.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

The invention will now be described in more detail by the following examples, which are illustrative only and do not limit the scope of the invention.

The following parameters are used:
μ is the charge carrier mobility
W is the length of the drain and source electrode (also known as “channel width”)
L is the distance between the drain and source electrode (also known as “channel length”)
I_{D} is the source-drain current
C₀ is the capacitance
V_{G} is the gate voltage (in V)
V_{D} is the source-drain voltage
V_{T} is the threshold voltage

Unless stated otherwise, all values of physical parameters as given above and below, like the permittivity (∈) or charge carrier mobility (μ), refer to a temperature of 20° C. (+/−1° C.). The molecular weight of oligomers and polymers means the weight average molecular weight M_{W}, which can be determined by GPC in a suitable solvent against polystyrene standards.

### Example 1

### Investigation of the Solvent Impact on BG OFET Devices

BG OFET devices were prepared comprising the following components
a gate electrode of Al prepared by evaporation through a shadow mask,
a gate dielectric layer of Merck Lisicon™ D181 (from Merck KGaA) prepared by spin coating and then cureing by 254 nm UV irradation,
source and drain electrodes of Ag prepared by evaporation through a shadow mask,
a self-assembled monolayer of Merck Lisicon™ M001 (from Merck KGaA), applied to the electrodes by spin coating, and
an OSC layer prepared by ink-jetting of a solution of the OSC compounds 2,8-difluoro-5,11-bis(triethylsilylethynyl)anthra[2,3-b:6,7-b′]dithiophene and 2,8-difluoro-5,11-bis(triethylsilylethynyl)anthra[2,3-b:7,6-b′]dithiophene (as a 50/50 mixture of both isomers) in mesitylene.

The devices were exposed to different solvents for 3 min. The linear mobility of the devices before and after the solvent exposure was compared.

The device performance of the 50 μm channel devices before and after solvent exposure was quantified by measuring the source-drain current and transistor mobility as a function of the gate voltage. The gate voltage was measured between 20 and −60V by using an Agilent 4155 semiconductor parameter analyzer.

The device performance was quantified using the ration between off and on current. Additionally the linear device mobility μ_{FE} was derived by using the standard thin film transistor equation (1):

$${I}_{D} = {μ}_{FE} {C}_{0} ( \frac{W}{L} ) \{ ( {V}_{G} - {V}_{T} ) {V}_{D} - ( \frac{{V}_{D}^{2}}{2} ) \} \qquad ( 1 )$$

where I_{D} is the drain current, C₀ is the capacitance, W/L is the device aspect ratio, V_{G} is the source drain voltage, V_{T} is the threshold voltage and V_{D} is the Drain-Source Voltage. The results are shown in Table 1 below.

TABLE 1

| | Linear Mobility (cm²/Vs) | | |
|---|---|---|---|
| | before | after 3 min | Performance |
| Solvent | exposure | solvent exposure | loss |
| Water | 1 | 1 | 0% |
| 9% Cytop-809M/FC43⁽¹⁾ | 0.36 | 0.37 | 0% |
| Ethylene glycol | 1 | 0.85 | 15% |
| FC 43 | 0.7 | 0.5 | 30% |
| Diethylene glycol | 0.7 | 0.4 | 43% |
| 9% Cytop-809M/FC43⁽²⁾ | 0.65 | 0.35 | 46% |
| 9% Cytop-809M/FC43⁽³⁾ | 0.89 | 0.43 | 52% |
| Sulfolane⁽⁴⁾ | 0.625 | 0.0951 | 85% |
| Propylene Carbonate | 0.806 | 0.0968 | 88% |
| Isopropyl alcohol | 0.64 | 0.048 | 93% |
| γ-Butyrolactone | 0.92 | 0.016 | 98% |
| Acetonitrile | 0.7 | 4 × 10⁻³ | 99% |
| Methanol | 0.7 | Destroyed | 100% |
| Ethanol | 0.8 | Destroyed | 100% |
| Acetic Acid | 0.85 | Destroyed | 100% |

⁽¹⁾spin coated
⁽²⁾ink-jetted, Merck M001 applied for 15 s
⁽³⁾ink-jetted, Merck M001 applied for 1 min
⁽⁴⁾is a solid at RT and had to be warmed to be used and to be removed from the device after solidifying.

The results show that only water and fluorinated solvents are orthogonal to the OSC and do not cause any performance loss due to possible dissolution of the OSC, whereas the other solvents lead to a significant performance loss of the device caused by dissolution of the OSC.

### Example 2

### Double Passivation Layer for Optimum Chemical Resistance

BG OFET devices were prepared comprising the following components
a gate electrode of Al prepared by evaporation through a shadow mask,
a gate dielectric layer of Merck Lisicon™ D206 (from Merck KGaA) prepared by spin coating and curing with >300 nm UV radiation,
source and drain electrodes of Ag prepared by evaporation through a shadow mask,
a self-assembled monolayer of Merck Lisicon M001 (from Merck KGaA), applied to the electrodes by spin coating, and
an OSC layer prepared by spin coating a solution of the OSC compounds 2,8-difluoro-5,11-bis(triethylsilylethynyl)anthra[2,3-b:6,7-b′]dithiophene and 2,8-difluoro-5,11-bis(triethylsilylethynyl)anthra[2,3-b:7,6-b′]dithiophene (as a 50/50 mixture of both isomers) in ethoxybenzene and cyclopentanol (5% of total formulation weight) as a solvent.

The devices were passivated by a double layer approach:

First a fluorinated orthogonal passivation material (9% Asahi Glass Cytop-809M in 3M FC43 T=278K) was deposited by spin coating (speed 5000 rpm, acceleration 6000 rpm/s, duration 8 s). The passivation layer was cured for 2 min at 100° C.

Subsequently a silicone protective passivation (Dow Corning Syl-Off 7681-030, Dow Corning Syl-Off 7682, Dow Corning Syl-Off 4000 ratio 12.5:1.5:0.25) was deposited by spin coating (speed 1500 rpm, acceleration 1000 rpm/s, duration 30 s) and cured for 15 min at 100° C.

The devices were then exposed to the following conditions, to simulate stages of a photo lithographic process. The passivated devices were exposed for 3 min to either 10% H₃PO4 (40° C.), 10% HNO₃ (40° C.), or 55% FN (20° C.). After washing with de-ionized water, the devices were exposed for 3 min to a 50:50 mixture of N-methylpyrrolidone/diethyleneglycol monoethyl ether mix 50:50 (60° C.). Finally the devices were washed.

The device performance was measured as outlined in Example 1. Table 2 shows the linear device mobility values for the devices.

TABLE 2

Linear Mobility
(cm²/Vs)

| | before | after | |
|---|---|---|---|
| Etchant | exposure | exposure | Performance |
| 10% phosphoric acid | 0.7 | 0.7 | Maintained |
| 10% nitric acid | 0.8 | 0.8 | Maintained |
| 55% ferric nitrate | 0.9 | 0.9 | Maintained |

It can be seen that the mobility values before and after passivation deposition and chemical exposure do not show any significant difference for any etchant option. This shows that the passivation layer provides sufficient protection against exposure.

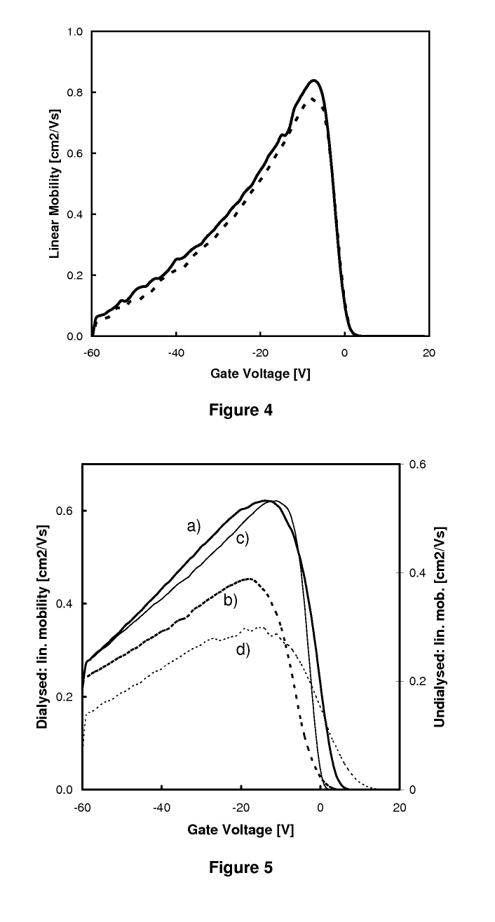

FIG. 4 shows the transistor mobility as a function of the gate voltage for the device exposed to 10% nitiric acid (40° C.). The solid line represents the mobility before passivation, the dotted line represents the mobility after passivation and acid exposure. It can be seen that the mobility values before and after passivation and exposure do not show any significant difference.

### Example 3

### Effect of the Ion Concentration in an Aqueous Based Passivation Formulation

The following example shows how removal of ions from an aqueous based passivation material can improve the retained performance after passivation layer deposition (i.e. reduce the loss in performance caused by the passivation process).

BG OFET devices were prepared as described in Example 1. The devices were then passivated by depositing an either dialysed or undialysed aqueous based orthogonal passivation material onto the OSC layer.

An undialysed batch of the ethylene modified poly-(vinyl alcohol) passivation material (Kuraray Exceval HR3010) was prepared by dissolving 10 g of polymer in 100 g of water by bringing the water to boil while the polymer/water mixture was stirred.

A dialysed batch of the same passivation material was prepared by dialyzing the above solution (cellulosis tubing, Mw˜14,000). 100 ml of polymer solution in the tubing was submersed in 5 L of de-ionised water having a conductivity <10 mS·cm⁻¹. The dialysis water was exchanged every day for 2 weeks.

The undialysed or dialysed passivation material, respectively, was deposited onto the OSC layer by spin coating (speed 5000 rpm, acceleration 6000 rpm/s, duration 15 s). The passivation layer was cured for 15 min at 100° C.

The device performance of both devices was measured as outlined in Example 1. FIG. 5 shows the linear mobility as a function of the gate voltage for devices with a passivation layer using

a) dialysed material, before passivation,
b) dialysed material, after passivation,
c) undialysed material, before passivation,
d) undialysed material, after passivation.

The unpassivated devices a) and c) show almost the same values, the difference being due to tolerable deviations in preparing the devices. When comparing the passivated devices b) and d), it can be seen that the mobility of the device b) passivated with dialysed material is reduced to 70% of the corresponding unpassivated device a), whereas the mobility of the device d) passivated with undialysed material is reduced to 55% of the corresponding unpassivated device c).

This shows that application of an aqueous based passivation material directly onto the OSC layer will lead to a decrease of the device mobility, and that the decrease can be reduced when the aqueous passivation material is dialysed to remove ionic impurities before being deposited onto the OSC layer.

The ion concentration in an aqueous formulation of the modified polyvinylaclohol Exceval HR3010 (from Kuraray) was quantified by measuring the conductivity of the formulation before and after dialysis. The conductivities were compared with de-ionised water and potassium chloride standard solutions. The results are shown in Table 3 below.

TABLE 3

| Formulation/Solution | Conductivity (muS cm⁻¹) |
|---|---|
| d.i. water | 0.75 |
| KCl 10⁻¹ mol L⁻¹ | 13.86 |
| KCl 10⁻² mol L⁻¹ | 1.42 |
| KCl 10⁻³ mol L⁻¹ | 0.1519 |
| KCl 10⁻⁴ mol L⁻¹ | 0.0177 |
| Kuraray Exceval HR3010/water 9% | 680 |
| (crude) | |
| Kuraray Exceval HR3010/water 9% | 27 |
| (dialysed) | |
| BDH poly-(vinyl pyrrolidone) | 21 |
| Mw~700,000 (crude) | |

The conductivity measurements confirm that the dialysed material has a much lower conductivity and ion content. The impurities have been removed from the polymer.

### Example 4

### Cross-Linked Passivation Layer

BG OFET devices were prepared as described in Example 1. The devices were passivated with an aqueous based orthogonal passivation layer as follows.

A solution of ethylene modified poly-(vinyl alcohol) passivation material (Kuraray Exceval HR3010) was prepared by dissolving 10 g of polymer in 100 g of water by bringing the water to boil while the polymer/water mixture was stirred.

1 ml of aqueous 40% solution of glyoxal (Merck) was slowly added to 10 g of the polymer solution while stirring. After adding the glyoxal, the solution was stirred for a further 15 min. The solution was allowed to rest until bubble free and used immediately.

The material was deposited by spin coating (speed 15 s at 500 rpm followed by 30 s at 1500 rpm, acceleration 1000 rpm/s). The passivation layer was cured for 15 min at 100° C.

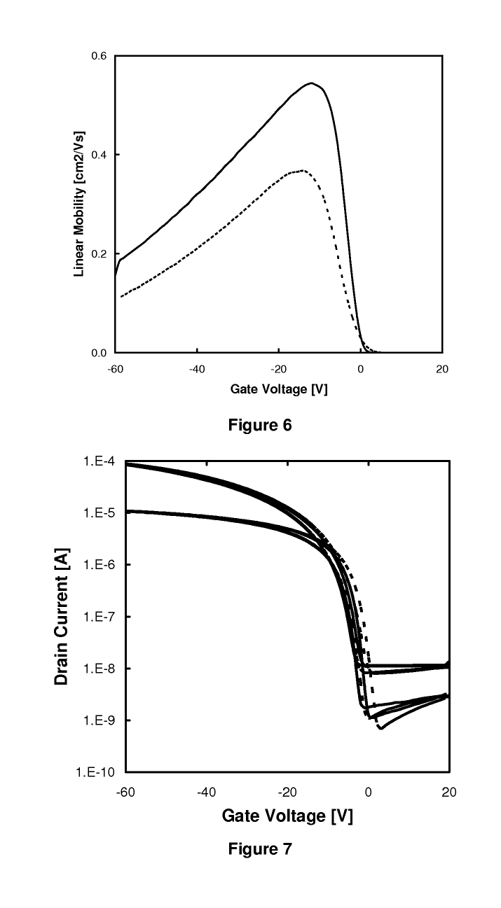

The device performance was measured as outlined in Example 1. FIG. 6 shows the linear mobility as a function of the gate voltage before passivation (solid line) and after passivation (dotted line). The device mobility typically shows the same performance reduction as without the addition of glyoxal.

The results show that this cross-linker, even though it has a low molecular weight, can be used to cross-link the material without loss of performance.

### Example 5

### Deposition of Orthogonal Layers at Low Spin Speed (Increased Deposition Time)

BG OFET devices were prepared comprising the following components:
a gate electrode of Al prepared by evaporation through a shadow mask,
a gate dielectric layer of Merck Lisicon® D206 (from Merck KGaA) prepared by spin coating and curing with >300 nm UV radiation,
source and drain electrodes of Ag prepared by evaporation through a shadow mask,
a self-assembled monolayer of Merck Lisicon® M001 (from Merck KGaA), applied to the electrodes by spin coating, and
an OSC layer prepared by spin coating a solution of the semiconducting compounds 2,8-difluoro-5,11-bis(triethylsilylethynyl)anthra[2,3-b:6,7-b′]dithiophene and 2,8-difluoro-5,11-bis(triethylsilylethynyl)anthra[2,3-b:7,6-b′]dithiophene (as a 50/50 mixture of both isomers) in ethoxybenzene and cyclopentanol (5% of total formulation weight) as a solvent.

The devices were passivated by a double layer approach:

First a fluorinated orthogonal passivation material (9% Asahi Glass Cytop® 809M in 3M FC43 T=278K) was deposited by spin coating (speed 1500 rpm, acceleration 1000 rpm/s, duration 8 s). The passivation layer was cured for 2 min at 100° C.

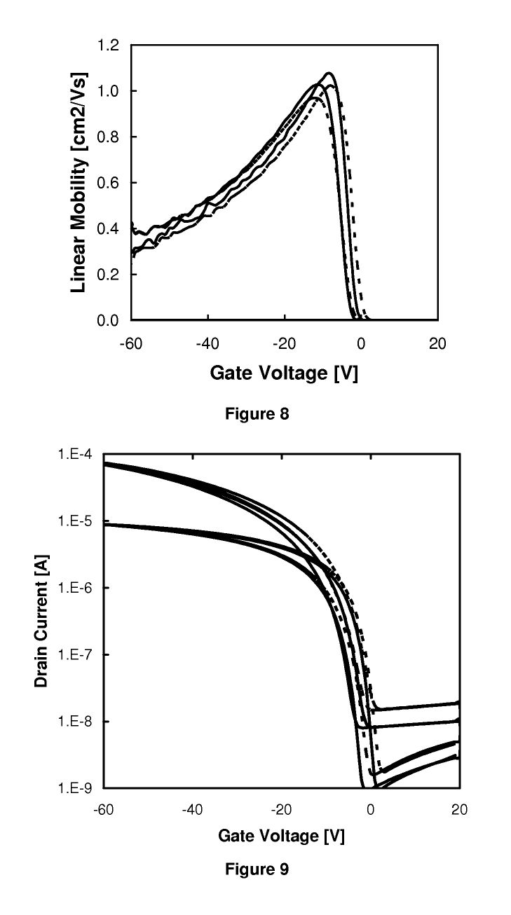

The device performance was measured as outlined in Example 1. FIG. 7 shows the transistor mobility as a function of the gate voltage, and FIG. 8 shows the transfer current as a function of gate voltage. The solid line represents the data before passivation, the dotted line represents the data after passivation. It can be seen that the performance values before and after passivation do not show any significant difference.

12.5 g of Dow Corning Syl-Off 7681-030 and 1.5 g of Dow Corning Syl-Off 7682 were mixed. The formulation did not cure over a period of 30 days at RT or 24 hours at 80° C. as indicative by any apparent increase in viscosity.

### Example 6

### Double Layer Passivation with Increased x-Linker Concentration in the Protective Layer

This system enables to reduce delamination of the protective layer from the orthogonal layer.

BG OFET devices were prepared comprising the following components
a gate electrode of Al prepared by evaporation through a shadow mask,
a gate dielectric layer of Merck Lisicon® D206 (from Merck KGaA) prepared by spin coating and curing with >300 nm UV radiation,
source and drain electrodes of Ag prepared by evaporation through a shadow mask,
a self-assembled monolayer of Merck Lisicon® M001 (from Merck KGaA), applied to the electrodes by spin coating, and
an OSC layer prepared by spin coating a solution of the semiconducting compounds 2,8-difluoro-5,11-bis(triethylsilylethynyl)anthra[2,3-b:6,7-b′]dithiophene and 2,8-difluoro-5,11-bis(triethylsilylethynyl)anthra[2,3-b:7,6-b′]dithiophene (as a 50/50 mixture of both isomers) in ethoxybenzene and cyclopentanol (5% of total formulation weight) as a solvent.

The devices were passivated by a double layer approach:

First a fluorinated orthogonal passivation material (9% Asahi Glass Cytop® 809M in 3M FC43 T=278K) was deposited by spin coating (speed 5000 rpm, acceleration 6000 rpm/s, duration 8 s). The passivation layer was cured for 2 min at 100° C.

Subsequently a silicone protective passivation (Dow Corning Syl-Off 7681-030, Dow Corning Syl-Off 7682, Dow Corning Syl-Off 4000 ratio 12.5:3.0:0.25) was deposited by spin coating (speed 1500 rpm, acceleration 1000 rpm/s, duration 30 s) and cured for 15 min at 100° C.

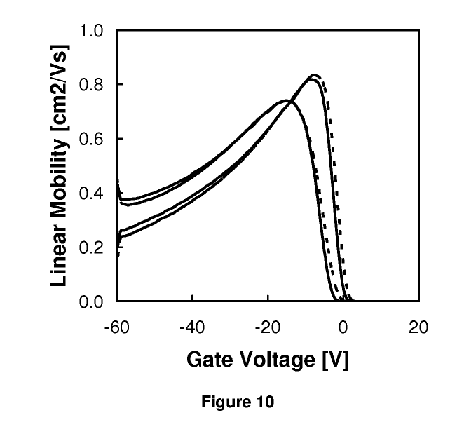

The device performance was measured as outlined in Example 1. FIG. 9 shows the transistor mobility as a function of the gate voltage and FIG. 10 shows the transfer current as a function of gate voltage. The solid line represents the data before passivation, the dotted line represents the data collected two month after passivation. It can be seen that the performance does not show any significant drop after passivation and with time.

1. Process for preparing a passivation layer for an organic electronic device, comprising the steps of
a) providing an organic semiconductor layer,
b) depositing a first passivation layer from a first formulation comprising a passivation material and one or more solvents onto the organic semiconductor layer and removing the solvents,
c) optionally depositing a second passivation layer from a second formulation comprising a passivation material and optionally one or more solvents onto the first passivation layer and removing the solvents if present,
wherein the solvents contained in the first formulation are selected from water or fluorinated organic solvents, and
wherein, if the first formulation comprises water as a solvent, the first formulation is treated to remove ionic impurities before deposition onto the organic semiconductor.

2. Process according to claim 1, characterized in that the first formulation contains water as a solvent, and is treated to remove ionic impurities before deposition on the organic semiconductor.

3. Process according to claim 1, characterized in that the treatment to remove ionic impurities comprises dialysis, reverse osmosis, ultrafiltratrion, microfiltration or nanofiltration.

4. Process according to claim 1, characterized in that the first formulation contains water as a solvent and a passivation material selected from water soluble hydrocarbon polymers, oligomers, polymer precursors, polymerisable compounds, or mixtures of any of the aforementioned.

5. Process according to claim 1, characterized in that the first formulation contains a fluorinated organic solvent and a passivation material selected from fluorinated hydrocarbon polymers, oligomers, polymer precursors, polymerisable compounds, or mixtures of any of the aforementioned.

6. Process according to claim 1, characterized in that the second formulation does not contain a solvent.

7. Process according to claim 1, characterized in that the second formulation contains a passivation material selected from silicon polymers, oligomers, polymer precursors, polymerisable compounds, or mixtures of any of the aforementioned.

8. Process according to claim 1, characterized in that the passivation material of the first and/or second formulation is cross-linked after deposition.

9. Process according to claim 1, characterized in that the organic semiconductor layer contains a compound selected from substituted pentacenes, substituted tetracenes, substituted anthracenes, or heterocyclic derivatives thereof.

10. Organic electronic device obtained by a process according to claim 1.

11. Organic electronic device according to claim 10, characterized in that it is selected from the group consisting of organic field effect transistors (OFET), thin film transistors (TFT), components of integrated circuitry (IC), radio frequency identification (RFID) tags, organic light emitting diodes (OLED), electroluminescent displays, flat panel displays, backlights, photodetectors, sensors, logic circuits, memory elements, capacitors, organic photovoltaic (OPV) cells, charge injection layers, Schottky diodes, planarising layers, antistatic films, conducting substrates or patterns, photoconductors, photoreceptors, electrophotographic devices and xerographic devices.

12. Electronic device according to claim 10, characterized in that it is a bottom gate OFET.
